(19) United States
(12) Patent Application Publication
(10) Pub. No.: US 2016/0358789 A1
(43) Pub. Date: Dec. 8, 2016

(54) APPARATUS FOR DECREASING SUBSTRATE TEMPERATURE NON-UNIFORMITY

(71) Applicant: Applied Materials, Inc., Santa Clara, CA (US)

(72) Inventors: Aaron MILLER, Sunnyvale, CA (US); Norman L. TAM, Cupertino, CA (US); Michael LIU, Saratoga, CA (US)

(21) Appl. No.: 15/170,982

(22) Filed: Jun. 2, 2016

Related U.S. Application Data
(60) Provisional application No. 62/171,551, filed on Jun. 5, 2015.

(51) Int. Cl. H01L 21/324; H01L 21/67

(52) U.S. Cl. CPC H01L 21/324; H01L 21/67115; H01L 21/67109; H01L 21/67248

(57) ABSTRACT

Embodiments of the present disclosure provide a cover assembly that includes a cover having a plurality of ports, and each port has a diameter of less than 1 mm, such as between about 0.1 mm to about 0.9 mm. The cover may be disposed between a device side surface of a substrate and a reflector plate, which are all disposed within a thermal processing chamber. The presence of the cover having the plurality of small ports within the thermal processing chamber will improve thermal uniformity over time after processing doped substrates.

### CLAIM OF PRIORITY UNDER 35 U.S.C. 119

This application claims priority to U.S. Provisional Patent Application Ser. No. 62/171,551, filed on Jun. 5, 2015, which herein is incorporated by reference.

### BACKGROUND

Field

Embodiments of the present disclosure generally relate to an apparatus for thermally processing a substrate.

Description of the Related Art

Substrate processing systems are used to fabricate semiconductor logic and memory devices, flat panel displays, CD ROMs, and other devices. During processing, such substrates may be subjected to chemical vapor deposition (CVD) and rapid thermal processes (RTP); RTP include, for example, rapid thermal annealing (RTA), rapid thermal cleaning (RTC), rapid thermal CVD (RTCVD), rapid thermal oxidation (RTO), and rapid thermal nitridation (RTN). RTP systems usually include heating lamps, LED's, lasers, or combinations thereof, which radiatively heat the substrate through a light-transmissive window. RTP systems may also include other optical elements, such as an optically reflective surface opposing of the substrate surface and optical detectors for measuring the temperature of the substrate during processing.

Ion implantation is a method for introduction of chemical impurities into semiconductor substrates to form the pn junctions for field effect or bipolar transistor fabrication. Such impurities include p-type dopants such as boron (B), aluminum (Al), gallium (Ga), beryllium (Be), magnesium (Mg), and zinc (Zn) and n-type dopants such as phosphorus (P), arsenic (As), antimony (Sb), bismuth (Bi), selenium (Se), and tellurium (Te). Ion implantation of chemical impurities disrupts the crystallinity of the semiconductor substrate over the range of the implant. At low implant energies, relatively little damage occurs to the substrate. However, the implanted dopants will not come to rest on electrically active sites in the substrate. Therefore, an anneal process is utilized to restore the crystallinity of the substrate and drive the implanted dopants onto electrically active crystal sites. Thermal processes such as RTP may be used to activate dopants.

It has been found that thermal uniformity across the substrate during processing degrades over time after processing As-doped substrates. FIG. 2A is a chart showing degrading thermal uniformity across the substrate during processing after processing heavily As-doped substrates. As shown in FIG. 2A, prior to processing doped substrates, the temperature (shown in the y-axis as sheet resistance Rs) profile across the substrate (shown in the x-axis as linescan) is shown as curve “Pre.” After processing 25 heavily As-doped substrates, the temperature profile across the substrate is shown as curve “After 25.” After processing 100 heavily As-doped substrates, the temperature profile across the substrate is shown as curve “After 100.” After processing 500 heavily As-doped substrates, the temperature profile across the substrate is shown as curve “After 500.” As shown in FIG. 2A, the temperature profiles of curves After 500, After 100, and After 25 clearly are less uniform than the curve Pre.

Therefore, an improved apparatus is needed to improve thermal uniformity during processing.

### SUMMARY

Embodiments of the present disclosure generally relate to an apparatus for thermally processing a substrate. In one embodiment, a process chamber includes a substrate support, an energy source facing the substrate support, a reflector plate having a reflective surface, the substrate support is disposed between the energy source and the reflector plate, and a cover disposed between the reflector plate and the substrate support. The cover includes a plurality of ports, and each port of the plurality of ports has a diameter of less than 1 mm.

In another embodiment, a process chamber includes a substrate support, an energy source facing the substrate support, a reflector plate having a reflective surface, the substrate support is disposed between the energy source and the reflector plate, and a cover disposed between the reflector plate and the substrate support. The cover includes a plurality of ports, and each port of the plurality of ports has a diameter ranging from about 0.1 mm to about 0.9 mm.

In another embodiment, a method includes delivering electromagnetic energy from an energy source towards a substrate support during processing, wherein the substrate support is configured to support a non-device side surface of a substrate, and delivering a thermal processing gas to a cover volume region formed between a reflector plate and a cover. The cover is disposed between the reflector plate and the energy source, and at least a portion of the thermal processing gas delivered to the cover volume region flows from the cover volume region through a plurality of ports formed in the cover to a portion of the device side surface of the substrate. Each port of the plurality of ports has a diameter of less than 1 mm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross sectional view of a process chamber according to embodiments described herein.

FIG. 2 is a plan view of a cover configured to be disposed in the process chamber of FIG. 1 according to embodiments described herein.

FIGS. 3A-3B are charts illustrating the benefit of including the cover shown in FIG. 2 in the process chamber of FIG. 1 according to embodiments described herein.

FIG. 4 is a plan view of a cover configured to be disposed in the process chamber of FIG. 1 according to embodiments described herein.

To facilitate understanding, identical reference numerals have been used, where possible, to designate identical elements that are common to the figures. It is contemplated that elements disclosed in one embodiment may be beneficially utilized in other embodiments without specific recitation.

### DETAILED DESCRIPTION

Embodiments of the present disclosure provide a cover assembly that includes a cover having a plurality of ports, and each port has a diameter of less than 1 mm, such as between about 0.1 mm to about 0.9 mm. The cover may be disposed between a device side surface of a substrate and a reflector plate, which are all disposed within a thermal processing chamber. The presence of the cover having the plurality of small ports within the thermal processing chamber will improve thermal uniformity during processing over time after processing doped substrates.

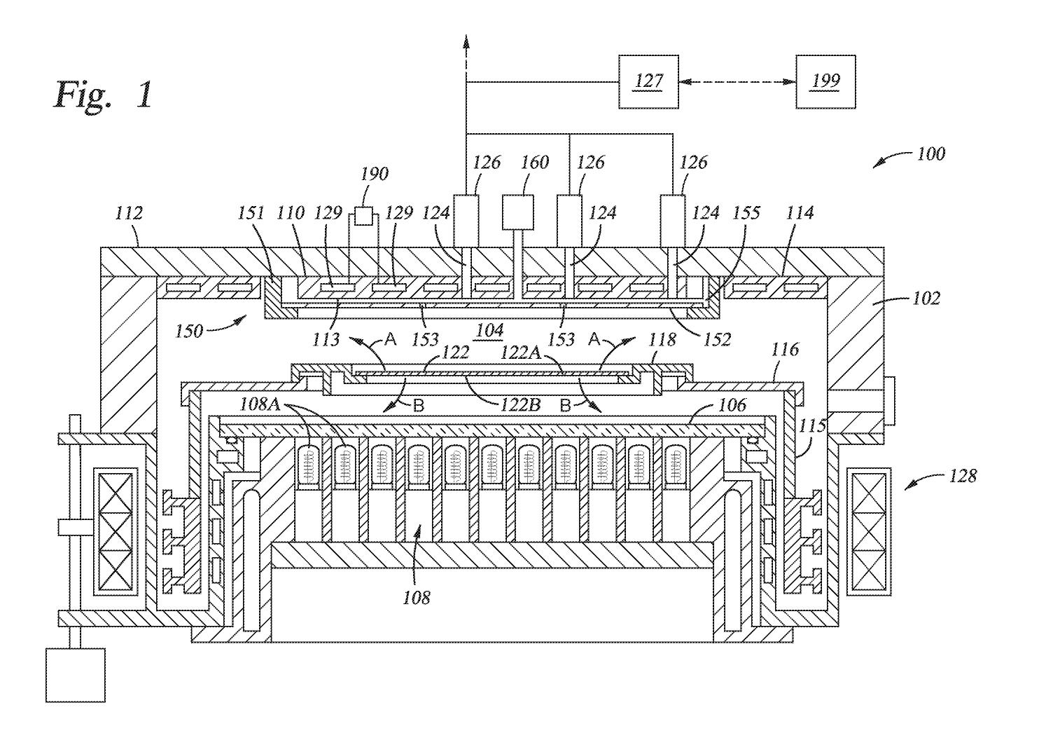

FIG. 1 is a schematic cross sectional view of a process chamber 100 according to embodiments described herein. The process chamber 100 may be a thermal processing chamber, such as an RTP chamber. The process chamber 100 includes a chamber body 102 defining a processing volume 104 and a system controller 199, which is adapted to control the various processes performed within the process chamber 100. Generally, the system controller 199 includes one or more processors, memory, and instructions suitable for controlling the operation of the components within the process chamber 100.

A radiant source window 106 may be formed on a bottom side of the chamber body 102. The radiant source window 106 may be formed from quartz or other similar material that is optically transparent to the electromagnetic energy delivered from lamps 108A disposed within a radiant energy source 108. Transparent used herein is defined as transmitting at least 95% of light of a given wavelength or spectrum. The radiant energy source 108, which is disposed below the window 106, is configured to direct radiant energy towards a non-device side surface 122B of a substrate 122 that is disposed within the processing volume 104. Words such as below, above, up, down, top, and bottom described herein do not refer to absolute directions, but to directions relative to a basis of the process chamber 100. A reflector plate 110 may be disposed on an upper wall 112 of the chamber body 102 inside the processing volume 104. In one configuration, a water cooled metal plate 114 is positioned around the edge of the reflector plate 110 to further provide cooling to the upper wall 112 during processing. A plurality of sensors 126, such as pyrometers, may be positioned over the upper wall 112 to detect temperatures of the substrate 122 and other related components in the processing volume 104 through sensor ports 124 formed in the reflector plate 110 and the upper wall 112. The plurality of sensors 126 may communicate with a temperature controller 127 that is adapted to receive signals from the sensors 126 and to communicate the received data to the system controller 199.

The process chamber 100 may also include a lift assembly 128 that is configured to vertically move and rotate a rotor 115 disposed in the processing volume 104. A supporting ring 116 may be disposed on the rotor 115. An edge ring 118, or substrate support or substrate supporting element, may be supported by the supporting ring 116. The substrate 122 may be supported by the edge ring 118 during processing. The edge ring 118 and the substrate 122 are positioned above the radiant energy source 108 so that the radiant energy source 108 is disposed facing the substrate support, including the edge ring 118 and the supporting ring 116. In this way, the radiant heat source 108 can heat both the substrate 122 and the edge ring 118.

The reflector plate 110 generally includes a reflecting surface 113 and typically includes cooling channels 129 formed within the body of the reflector plate 110. The cooling channels 129 are coupled to a fluid delivery device 190 that is configured to cause a cooling fluid to flow within the cooling channels 129 to maintain the reflector plate 110 and upper wall 112 at a predetermined temperature. In one example, the reflector plate 110 is maintained at a temperature between about 50 and 150° C., such as about 75° C. The reflecting surface 113 is configured to reflect/redirect the energy provided from the radiant energy source 108, or emitted by the substrate 122, the edge ring 118, and/or the supporting ring 116 back to the processing volume 104 and substrate 122.

The process chamber 100 generally includes a cover assembly 150 that is positioned between the upper wall 112 and the substrate 122. The cover assembly 150 may include a cover 152 and a cover support 151. The cover support 151 is configured to position and retain the cover 152 within the processing volume 104. In one configuration, the cover support 151 is positioned near the outer edge of the reflector plate 110 and is at least as large in diameter as the diameter of the substrate 122 (e.g., ≧300 mm for a 300 mm wafer). In one configuration, the cover support 151 is positioned between the outer edge of the reflector plate 110 and the inner edge of the water cooled metal plate 114. The cover support 151 may be bolted or mechanically coupled to the upper wall 112, reflector plate 110 or water cooled metal plate 114 to provide both structural and thermal coupling between the components in the cover assembly 150 (e.g., cover 152) and the upper wall 112, reflector plate 110 or water cooled metal plate 114. In another embodiment, the cover support 151 may be at least partially thermally isolated from the upper wall 112, reflector plate 110 or water cooled metal plate 114 by use of a thermally insulating materials or by adjusting the thermal contact between these parts.

The process chamber 100 also generally includes a gas source 160 that is configured to deliver a thermal process gas to a cover volume region 155 and then to the processing volume 104 and a device side surface 122A of the substrate 122 by use of ports 153, or through holes, formed through the cover 152. The thermal process gas may include an inert and/or a process gas that is provided to enhance the thermal processes performed within the processing volume 104. In one example, the thermal process gas may be a gas selected from a group consisting of nitrogen, argon, hydrogen, oxygen, helium, neon, a halogen gas, and other useful gases, and/or combinations thereof. In another example, the thermal process gas may be an inert gas, such as a gas selected from a group consisting of nitrogen, helium, neon and argon.

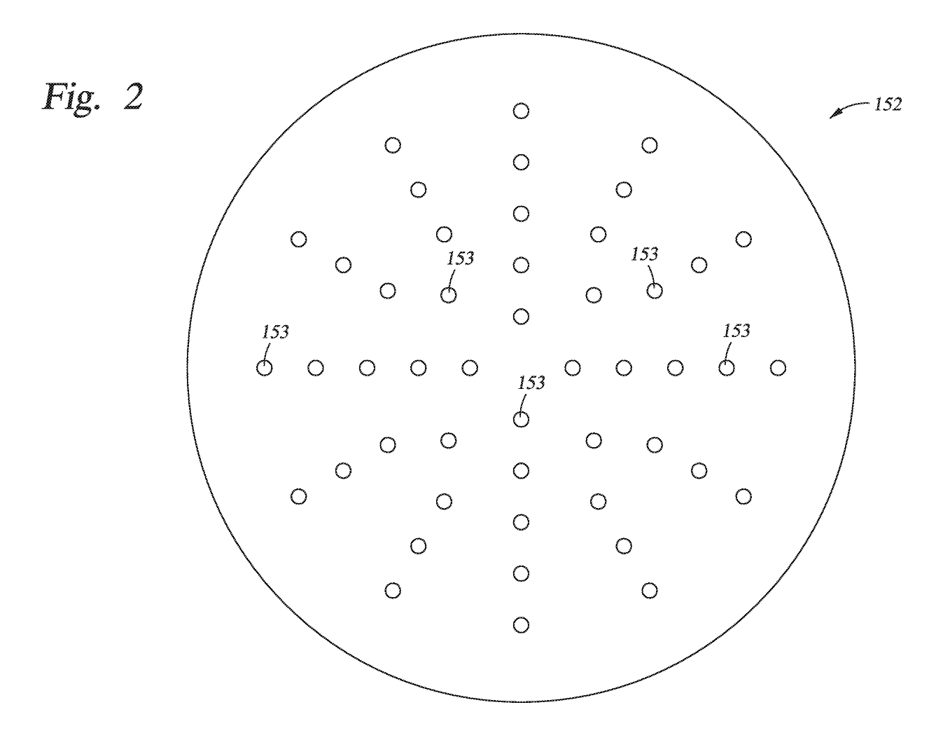

In general, the cover 152 acts as a physical barrier to the outgassed material, such as the p or n type dopant, that flows from the substrate towards the reflector plate 110 and sensors 126 during processing (e.g., material flux “A” in FIG. 2). In one embodiment, the cover 152 is positioned a distance from the reflecting surface 113 of the reflector plate 110, so as to form the cover volume region 155 between the cover 152 and the surface 113 of the reflector plate 110. The cover volume region 155 is at least a partially enclosed region that is bounded by the cover 152, cover support 151, reflector plate 110 and upper wall 112. In some configurations, the cover volume region 155 is at least partially sealed to allow a back pressure to form therein as a flow of a thermal process gas is provided by the gas source 160 to the cover volume region 155 and out of cover volume region 155 through the ports 153 formed in the cover 152. It has been surprisingly found that the back pressure formed in the cover volume region 155 keeps the thermal uniformity across the substrate from degrading over time.

Also, the thermal properties of the cover 152 will allow the cover 152 to act as a barrier to reduce the amount of deposition on the cover 152. In one example, the cover 152 is formed from an optically transparent material, such as flame fused quartz, electrically fused quartz, synthetically fused quartz, a high hydroxyl containing fused quartz (i.e., high OH quartz), sapphire, or other optically transparent material that has desirable optical properties (e.g., optical transmission coefficient and optical absorption coefficient). In one example, the cover includes a high hydroxyl containing fused quartz material that comprises a quartz material that has between about 600 and about 1,300 ppm of hydroxyl impurities. In one example, the cover 152 includes a high hydroxyl containing fused quartz material that comprises a quartz material that has between about 1,000 ppm and about 1,300 ppm of hydroxyl impurities. The cover support 151 may be formed from a metal or a thermally insulating material, such as stainless steel, fused quartz, alumina, or other material that is able to withstand the thermal processing temperatures and has desirable mechanical properties (e.g., similar coefficient of thermal expansion (CTE) to the material from which the cover 152 is made).

During processing, the radiant energy source 108 is configured to rapidly heat the substrate 122 positioned on the edge ring 118. The process of heating the substrate 122 will cause one or more layers on or within the substrate to outgas (see arrows “A” and “B”). Typically, the amount of material that is outgassed from the device side surface 122A of the substrate 122 (see arrows A) is greater than the amount of material outgassed from the non-device side surface 122B of the substrate 122 (see arrows B).

The amount of material that will deposit on the cover 152 will depend on the temperature of the cover 152 during processing. In general, temperature of the cover 152 is selected such that it is high enough to discourage condensation of the outgassed material, but low enough to discourage a reaction between the outgassed material and the material used to form the cover 152. A reaction between the outgassed material and the material used to form the cover 152 may affect the optical properties of the cover 152 over time, and thus cause a drift in the thermal processes performed in the process chamber 100.

FIG. 2 is a plan view of the cover 152 according to embodiments described herein. As shown in FIG. 2, the cover 152 includes the plurality of ports 153. There may be any suitable number of ports 153. In one embodiment, there are 52 ports 153, and of the 52 ports 153, 4 ports 153 are disposed on a 28 mm diameter circle, 8 ports 153 are disposed on a 69 mm diameter circle, 12 ports 153 are disposed on a 94 mm diameter circle, 12 ports 153 are disposed on a 121 mm diameter circle, and 12 ports 153 are disposed on a 146 mm diameter circle. The 28 mm diameter circle, the 69 mm diameter circle, the 94 mm diameter circle, and the 121 mm diameter circle may be concentric, and may be concentric with the cover 152. The size of the cover 152 may vary depending on the size of the substrate 122, and the pattern of the ports 153 may vary depending on the size of the cover 152. The pattern of the ports 153 may be configured so the process gases are evenly distributed to the device side surface 122A of the substrate 122. The pattern of the ports 153 may be symmetrical with respect to a central axis of the process chamber 100, or may be asymmetrical with respect to the central axis of the process chamber 100. The density of the ports 153 in the cover 152 may or may not be consistent across the cover 152. The ports 153 may have the same diameter, such as less than about 1 mm. Alternatively, the ports 153 may have different diameters in order to adjust process gas flow to compensate for systematic gas flow non-uniformities in the process chamber 100. If the diameters of the ports 153 are different, the largest diameter of the ports 153 is less than 1 mm, such as from about 0.1 mm to about 0.9 mm.

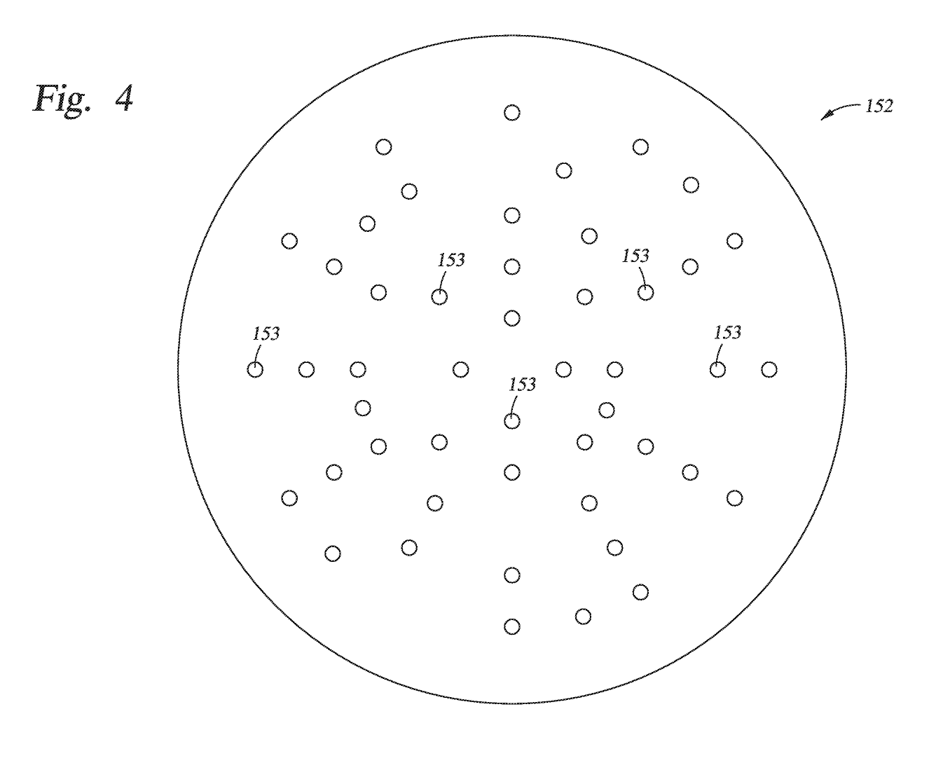

The arrangement of the ports 153 may also be used to provide temperature adjustment to selected areas of the substrate in some embodiments. For example, the arrangement of the ports may be selected to provide an increased gas flow toward a region of the substrate 122 to effect cooling in the region, if such cooling is desired. Such measures may be helpful in circumstances where temperature non-uniformities persist. The ports 153 may be arranged in a non-uniform arrangement such that gas flow through the ports partially or fully compensates such temperature non-uniformities. An example of the cover 152 having non-uniformly arranged ports 153 is shown in FIG. 4.

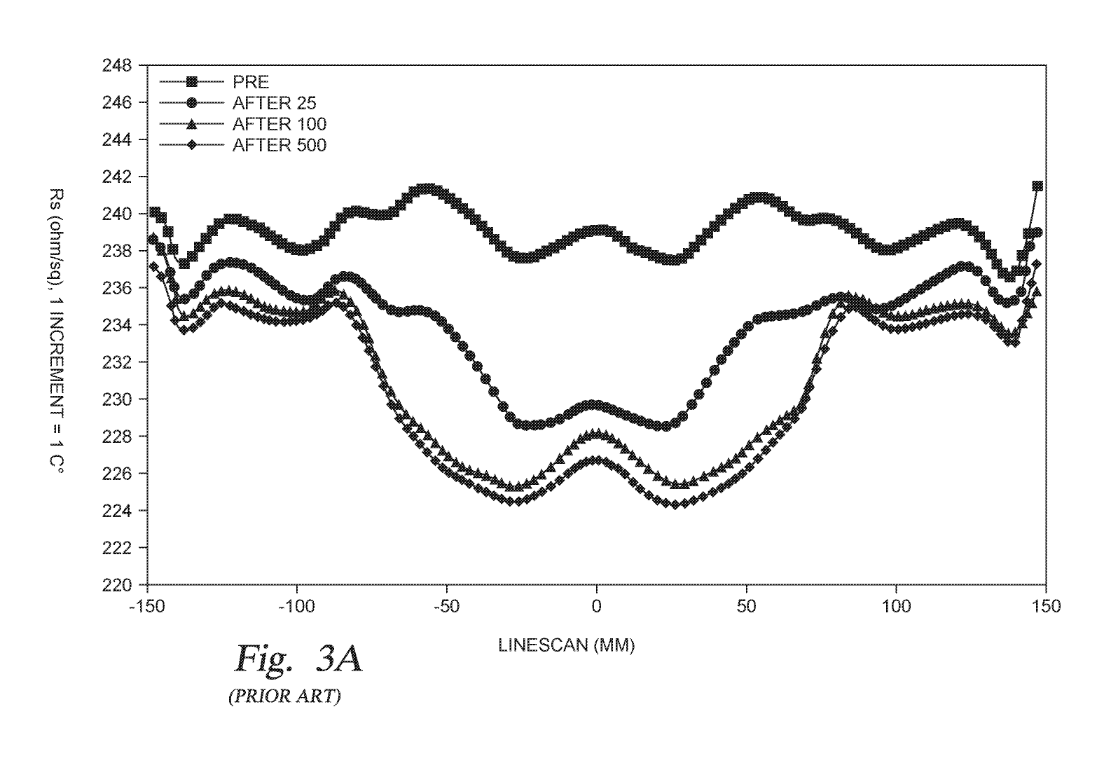

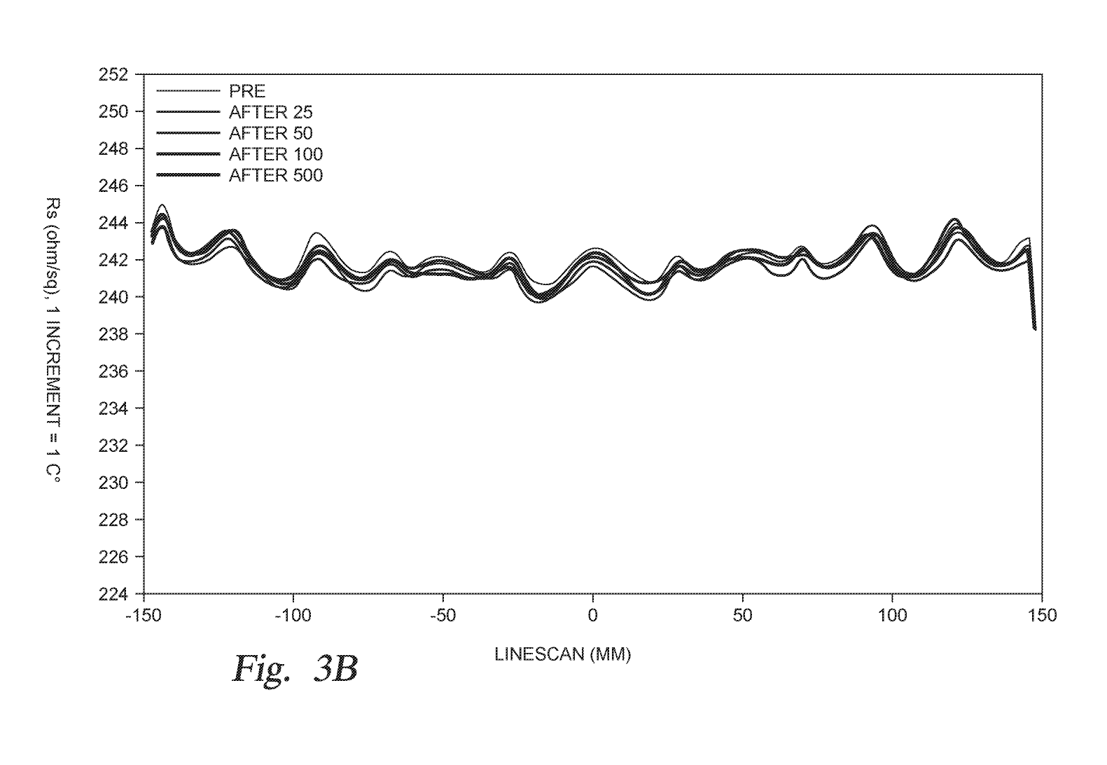

It has been surprisingly found that by decreasing the diameter of each port 153 to less than 1 mm, such as from about 0.1 mm to about 0.9 mm, the thermal uniformity across the substrate does not degrade over time after processing doped substrates. In one embodiment, each port 153 has a diameter ranging from about 0.25 mm to about 0.75 mm, such as about 0.5 mm. The effect of having smaller ports 153 on the thermal uniformity during processing is shown in FIG. 3B. As shown in FIG. 3B, the temperature profiles of prior to processing doped substrates, after processing 25 doped substrates, after processing 100 doped substrates, and after processing 500 doped substrates are substantially the same. Thus, thermal uniformity across the substrate does not degrade over time after processing doped substrates as the result of having smaller ports 153 formed in the cover 152.

While the foregoing is directed to embodiments of the present disclosure, other and further embodiments of the disclosure may be devised without departing from the basic scope thereof, and the scope thereof is determined by the claims that follow.

1. A process chamber, comprising:
a substrate support;
an energy source facing the substrate support;
a reflector plate having a reflective surface, wherein the substrate support is disposed between the energy source and the reflector plate; and
a cover disposed between the reflector plate and the substrate support, wherein the cover includes a plurality of ports, and wherein each port of the plurality of ports has a diameter of less than 1 mm.

2. The process chamber of claim 1, wherein the plurality of ports are arranged in a non-uniform arrangement.

3. The process chamber of claim 1, further comprising a window disposed between the substrate support and the energy source.

4. The process chamber of claim 1, wherein the cover comprises quartz.

5. The process chamber of claim 4, wherein the cover comprises fused quartz having between about 600 and about 1,300 ppm of hydroxyl impurities.

6. The process chamber of claim 1, wherein the cover comprises sapphire.

7. The process chamber of claim 1, wherein the reflector plate includes cooling channels.

8. The process chamber of claim 1, further comprising a metal plate disposed around the reflector plate.

9. The process chamber of claim 1, wherein each port of the plurality of ports has a diameter ranging from about 0.25 mm to about 0.75 mm.

10. A process chamber, comprising:
a substrate support;
an energy source facing the substrate support;
a reflector plate having a reflective surface, wherein the substrate support is disposed between the energy source and the reflector plate; and
a cover disposed between the reflector plate and the substrate support, wherein the cover includes a plurality of ports, and wherein each port of the plurality of ports has a diameter ranging from about 0.1 mm to about 0.9 mm.

11. The process chamber of claim 10, wherein the cover comprises quartz.

12. The process chamber of claim 11, wherein the cover comprises fused quartz having between about 600 and about 1,300 ppm of hydroxyl impurities.

13. The process chamber of claim 10, wherein the cover comprises sapphire.

14. The process chamber of claim 10, wherein the reflector plate includes cooling channels.

15. The process chamber of claim 10, further comprising a metal plate disposed around the reflector plate.

16. The process chamber of claim 10, wherein each port of the plurality of ports has a diameter ranging from about 0.25 mm to about 0.75 mm.

17. A method, comprising:
delivering electromagnetic energy from an energy source towards a substrate support during processing, wherein the substrate support is configured to support a non-device side surface of a substrate; and
delivering a thermal processing gas to a cover volume region formed between a reflector plate and a cover, wherein the cover is disposed between the reflector plate and the energy source, wherein at least a portion of the thermal processing gas delivered to the cover volume region flows from the cover volume region through a plurality of ports formed in the cover to a portion of the device side surface of the substrate, and wherein each port of the plurality of ports has a diameter of less than 1 mm.

18. The method of claim 17, wherein the thermal processing gas comprises an inert gas.

19. The method of claim 17, further comprising flowing a cooling fluid within cooling channels formed within the reflector plate.

20. The method of claim 17, further comprising measuring a temperature of a substrate during processing using one or more sensors, wherein the cover and cover volume region are disposed between the sensors and the substrate during processing.
